(19) United States
(12) Patent Application Publication
(10) Pub. No.: US 2005/0117422 A1
(43) Pub. Date: Jun. 2, 2005

(54) Semiconductor integrated circuit including semiconductor memory

(76) Inventors: Atsushi Urayama, Kawasaki-shi (JP); Kenichi Nakamura, Tokyo (JP); Shunichi Iwami, Sagamihara-shi (JP); Hirokazu Okano, Kawasaki-shi (JP); Machi Wada, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/975,336

(22) Filed: Oct. 29, 2004

(30) Foreign Application Priority Data
Nov. 5, 2003 (JP) 2003-375850

(51) Int. Cl. G11C 7/00

(52) U.S. Cl. 365/203

(57) ABSTRACT

A semiconductor integrated circuit is a synchronous semiconductor integrated circuit which operates in synchronism with a clock signal, and includes memory cells, bit lines, a pre-charge circuit and a pre-charge controlling circuit. The memory cells store information, and are connected to the bit lines. The pre-charge circuit performs a pre-charge operation for pre-charging a bit line. The pre-charge controlling circuit controls the pre-charge operation of the pre-charge circuit. The pre-charge controlling circuit synchronizes starting of the pre-charge operation with the edge of the clock signal.

### CROSS-REFERENCE TO RELATED APPLICATIONS

This application is based upon and claims the benefit of priority from Prior Japanese Patent Application No. 2003-375850, filed Nov. 5, 2003, the entire contents of which are incorporated herein by reference.

### BACKGROUND OF THE INVENTION

1. Field of the Invention

The present invention relates to a semiconductor integrated circuit including a semiconductor memory, e.g., a synchronous semiconductor memory which includes a test mode.

2. Description of the Related Art

In a semiconductor integrated circuit such as an ASIC on which an SRAM (static random access memory) and a logic circuit are combined, when an operation test of the SRAM is run, there is a case where it is run at a frequency lower than a frequency determined in accordance with the structure of the circuit. In this case, a write recovery failure which occurs when a reading operation is performed just after a writing operation cannot be detected. Why such a problem arises will be explained.

FIG. 1 is a circuit diagram of an example of a conventional SRAM.

In the conventional SRAM, memory cells 101 for storing data are arranged in a matrix as a memory cell array. In each of areas of the conventional SRAM, a pair of bit lines BL and /BL are provided for memory cells 101 arranged in a column direction as shown in FIG. 1.

Furthermore, a pre-charge circuit 102 is connected to the pair of bit lines BL and /BL, and is designed to pre-charge the pair of bit lines BL and /BL. To the pre-charge circuit 102, a pre-charge controlling circuit 103 for controlling the above pre-charging operation of the pre-charge circuit 102 is connected. To the pre-charge controlling circuit 103, a write pulse signal WRP output from a write pulse generating circuit 104 and a word line pulse signal WLP output from a word line pulse generating circuit 105 are input. A pre-charge signal PRE is output from the pre-charge controlling circuit 103.

FIG. 2 is a timing chart of internal signals in the SRAM at the time of testing the operation thereof at a high frequency. As can be seen from FIG. 2, at the time of a write operation (WRITE), when the write pulse signal WRP output from the write pulse generating circuit 104 rises (at a point A), the pre-charge signal PRE becomes “H”, the pre-charge operation of the pre-charge circuit 102 is stopped, and a data writing operation is performed on the bit lines (at a point B). Then, when the write pulse signal WRP falls (at a point A′), the pre-charge signal PRE becomes “L”, and the pre-charge operation of the pre-charge circuit 102 is started. Thereby, the bit lines are pre-charged (at a point B′).

In the case where the pre-charge circuit 102 normally operates, at the time of starting a read operation (READ), the bit lines are completely pre-charged (at a point C), and it is determined that the SRAM passes the above operation test. On the other hand, in the case where the pre-charge circuit 102 abnormally operates, for example, in the case where a parasitic resistance is present in the bit lines, and they cannot be normally pre-charged, at the time of starting the reading operation, pre-charging of the bit lines is incomplete (at a point C′), and it is determined that the SRAM fails the operation test.

FIG. 3 is a timing chart of internal signals in the SRAM at the time of testing the operation thereof at a low frequency. As can be seen from FIG. 3, in the case where the pre-charge circuit 102 normally operates, at the time of starting the reading operation, the bit lines are completely pre-charged (at a point F), and it is determined that the SRAM passes the operation test. Also, even in the case where the pre-charge circuit 102 abnormally operates, the bit lines are completely pre-charged (at a point F′), and it is thus determined that the SRAM passes the operation test. Accordingly, in the above operation test at a low frequency, a write recovery failure cannot be detected.

In order to solve such a problem, the following method is disclosed: an external input terminal is provided, and a mode of controlling a pre-charge signal with a signal input from the outside to the external input terminal is provided, to thereby to detect a write recovery failure (as disclosed in, e.g., Jpn. Pat. Appln. KOKAI Publication No. 2001-52498).

However, in an ASIC provided with an SRAM according to the method, it is necessary to provide an external input terminal and produce a signal (test pattern) to be input from the outside.

### BRIEF SUMMARY OF THE INVENTION

A semiconductor integrated circuit according to an aspect of the present invention is a synchronous semiconductor integrated circuit which operates in synchronism with a clock signal, and comprises a memory cell, a bit line, a pre-charge circuit and a pre-charge controlling circuit. The memory cell stores information, and is connected to the bit line. The pre-charge circuit performs a pre-charge operation for pre-charging the bit line. The pre-charge controlling circuit controls the pre-charge operation of the pre-charge circuit, and synchronizes starting of the pre-charge operation with an edge of the clock signal.

A semiconductor integrated circuit according to another aspect of the present invention is a synchronous semiconductor integrated circuit which operates in synchronism with a clock signal, and comprises a plurality of memory cells, a pair of bit lines, a pre-charge circuit and a pre-charge controlling circuit. The memory cells are arranged in a matrix. The pair of bit lines are connected to memory cells arranged in a column direction. The pre-charge circuit performs a pre-charge operation for pre-charging the pair of bit lines. The pre-charge controlling circuit controls the pre-charge operation of the pre-charge circuit. In the case where a writing operation is performed in a first time period of the clock signal, the pre-charge controlling circuit causes the pre-charge operation to be stopped in synchronism with an edge of the clock signal at the start of the first time period, and to be started in synchronism with an edge of the clock signal at the start of a second time period subsequent to the first time period.

### BRIEF DESCRIPTION OF THE SEVERAL VIEWS OF THE DRAWING

FIG. 1 is a circuit diagram of an example of a conventional SRAM.

FIG. 2 is a timing chart of internal signals in the SRAM at the time of testing the operation thereof at a high frequency.

FIG. 3 is a timing chart of internal signals in the SRAM at the time of testing the operation thereof at a low frequency.

FIG. 4 is a view showing for the structure of a semiconductor integrated circuit including an SRAM according to an embodiment of the present invention.

FIG. 5 is a timing chart of internal signals in the SRAM according to the embodiment of the present invention at an operation test time at a low frequency.

### DETAILED DESCRIPTION OF THE INVENTION

The embodiment of the present invention will be explained with reference to the accompanying drawings. In the following explanation, the same structural elements throughout the drawings will be denoted by the same reference numerals, respectively.

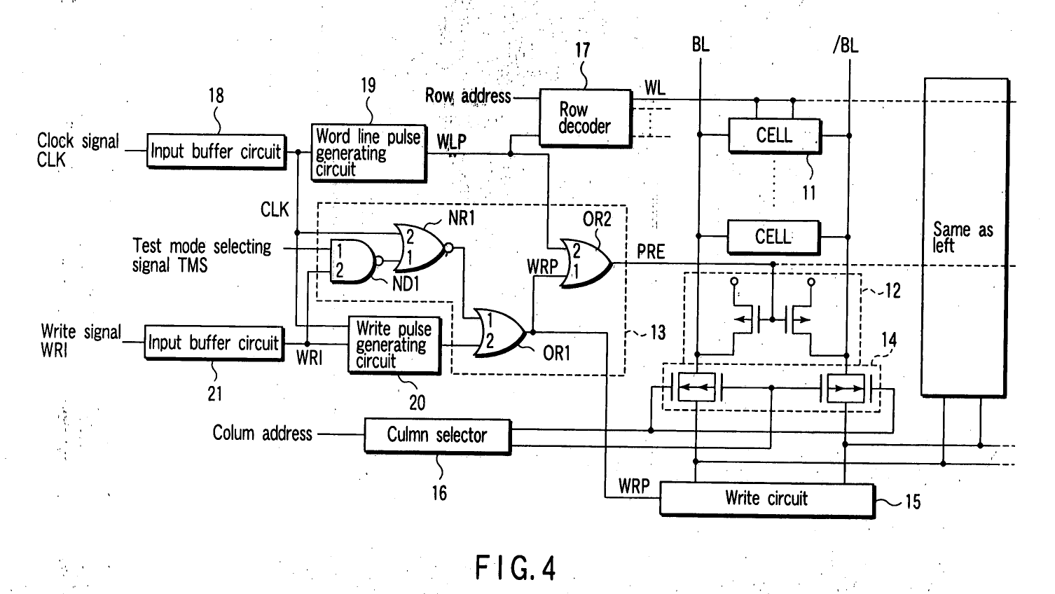

FIG. 4 is a view for showing the structure of a semiconductor integrated circuit including an SRAM according to the embodiment of the present invention. In the SRAM, memory cells (CELL) 11 for storing data are arranged in a matrix as a memory cell array. In each of areas of the SRAM, as shown in FIG. 4, a pair of bit lines BL and /BL are provided for memory cells 11 arranged in a column direction.

A pre-charge circuit 12 is connected to the pair of bit lines BL and /BL, and is designed to pre-charge the bit lines BL and /BL. Furthermore, a pre-charge controlling circuit 13 for controlling the pre-charging operation of the pre-charge circuit 12 is connected to the pre-charge circuit 12.

A write circuit 15 is connected to the bit lines BL and /BL by a switch circuit 14. To the switch circuit 14, a column selector 16 is connected. To the column selector 16, a column address is input. The column selector 16 controls the operation of the switch circuit 14 based on the column address.

Furthermore, word lines WL are connected to memory cells arranged in a row direction. The word lines WL are connected to a row decoder 17. The row decoder 17 receives a row address, and selects one of the word lines WL based on the row address.

A clock signal CLK input from the outside to an input buffer circuit 18 is input to a write pulse generating circuit 20, a pre-charge controlling circuit 13 and a word line pulse generating circuit 19 in this order. An output portion of the word line pulse generating circuit 19 is connected to the row decoder 17. Also, a write signal WRI input from the outside to an input buffer circuit 21 is input to the write pulse generating circuit 20 and the pre-charge controlling circuit 13.

The pre-charge circuit 13 comprises a NAND ND1, a NOR circuit NR1, and OR circuits OR1 and OR2. To a first input terminal of the NAND circuit ND1, a test mode selecting signal TMS is input, and to a second input terminal of the NAND circuit ND1, a write signal WRI is input. To a first input terminal of the NOR circuit NR1, an output signal of the NAND circuit ND1 is input, and to a second input terminal of the NOR circuit NR1, the clock signal CLK is input.

An output signal of the NOR circuit NR1 is input to a first input terminal of the OR circuit OR1, and an output signal of the write pulse generating circuit 20 is input to a second input terminal of the OR circuit OR1. Furthermore, a write pulse signal WRP output from the OR circuit OR1 is input to the write circuit 15 and a first input terminal of the OR circuit OR2, and a word line pulse signal WLP output from the word line pulse generating circuit 19 is input to a second input terminal of the OR circuit OR2. A pre-charge signal PRE is output from the OR circuit OR2, and input to the pre-charge circuit 12.

The operation of the SRAM according to the above embodiment in a test mode will be explained.

Switching between a regular operation mode and a test operation mode is effected in response to a test mode selecting signal TMS input to the NAND circuit ND1 in the pre-charge controlling circuit 13. In the regular operation mode, a regular operation is performed, and in the test operation mode, a test operation is performed.

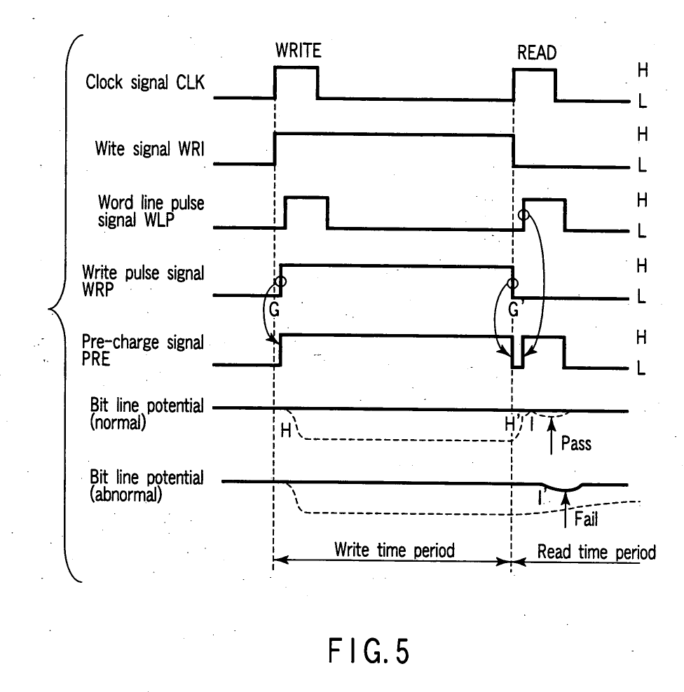

In a write time period in the test mode, when a write pulse signal WRP is subjected to a logical operation in the pre-charge circuit 13, it falls to become “L” in synchronism with a rising edge or a falling edge of the clock signal CLK at the start of a read time period subsequent to the write time period. In this case, in an example shown in FIG. 5, the write pulse signal WRP falls to become “L” in synchronism with the rising edge of the clock signal CLK. The pre-charge signal PRE falls to become “L” in synchronism with a falling edge of the write pulse signal WRP, as a result of which a pre-charge operation is started, and the bit lines are pre-charged. Then, when the word line pulse signal WLP, which activates a word line, rises, the pre-charge signal PRE rises to become “H” in synchronism with a rising edge of the word line pulse signal WLP, and as a result of which the pre-charge operation is stopped. Therefore, a pre-charge time period in the case where a reading operation is performed just after a writing operation is a time period from the time when the read time period starts to the time when the word line has been activated, and is not changed regardless of the frequency of the clock signal CLK in the test mode.

FIG. 5 is a timing chart of internal signals in the SRAM at the operation test time at a low frequency.

As can be seen from FIG. 5, after the writing operation is performed, the falling edge (point G′) of the write pulse signal WRP is synchronous with a rising edge of the clock signal CLK at the start of the read time period, at which the reading operation is carried out. The pre-charge signal PRE falls in synchronism with a falling edge of the write pulse signal WRP, the pre-charge operation is started, and the bit lines are pre-charged. Then, the pre-charge signal PRE rises in synchronism with a rising edge of the word line pulse signal WLP, and the pre-charge operation is stopped. When the pre-charge circuit 12 connected to the bit lines normally operates, at the time of starting the reading operation, the bit lines are completely pre-charged (at a point I), and it is determined that the SRAM passes the operation test. On the other hand, when the pre-charge circuit 12 connected to the bit lines abnormally operates, at the time of starting the reading operation, pre-charging of the bit lines is incomplete (at a point I′), and it is determined that the SRAM fails the operation test. Consequently, a write recovery failure can be detected.

The operation of the SRAM in the test mode, which includes the operation of the pre-charge controlling circuit 13, will be explained in detail.

“H” of the test mode selecting signal TMS indicates that the mode should be switched to the test mode, and “L” of the test mode selecting signal TMS indicates that the mode should be switched to the regular mode. When the test mode selecting signal TMS is input as “H” to the first input terminal of the NAND circuit ND1, and the write signal WRI is input as “H” to the second input terminal of the NAND circuit ND1, an output “L” is output from the NAND circuit ND1. The output “L” of the NAND circuit ND1 is input to the first input terminal of the NOR circuit NR1, and the clock signal CLK is input to the second input terminal of the NOR circuit NR1. When the clock signal CLK becomes “H” which indicates that the writing operation should be started, the output of the NOR circuit NR1 becomes “L”.

The output signal “L” of the NOR circuit NR1 is input to the first input terminal of the OR circuit OR1, and the output signal of the write pulse generating circuit 20 is input to the second input terminal of the OR circuit OR1. At this time, the output of the OR circuit OR1 is determined by the output signal of the write pulse generating circuit 20, since the output of the NOR circuit NR1 is “L”.

In this case, since the output of the write pulse generating circuit 20 is “H”, the write pulse signal WRP output from the OR circuit OR1 is also “H” (at a point G), and is input to the first input terminal of the OR circuit OR2. To the second input terminal of the OR circuit OR2, the word line pulse signal WLP output from the word line pulse generating circuit 19 is input. At this time, since an output “H” is input to the first input terminal of the OR circuit OR2, the pre-charge signal PRE output from the OR circuit OR2 is also “H” regardless of the word line pulse signal WLP. The pre-charge signal is input as “H” to the pre-charge circuit 12, and the pre-charge operation is stopped.

Next, when the clock signal CLK becomes “L”, an output “L” is input to the second input terminal of the NOR circuit NR1. At this time, the output of the NOR circuit NR1 is “H”, since the output of the NAND circuit ND1 which is input to the first input terminal of the NOR circuit NR1 remains unchanged, i.e., it is “L”. The output “H” of the NOR circuit NR1 is input to the first input terminal of the OR circuit OR1. Therefore, although the output signal of the write pulse generating circuit 20 is input to the second input terminal, the write pulse signal WRP output from the OR circuit OR1 is “H”, since the output “H” is input to the first input terminal of the OR circuit OR1. That is, the write pulse signal WRP output from the OR circuit OR1 is “H” regardless of the output signal of the write pulse generating circuit 20.

The output “H” of the OR circuit OR1 is input to the first input terminal of the OR circuit OR2. Therefore, although the word line pulse signal WLP is input to the second input terminal of the OR circuit OR2, the pre-charge signal PRE output from the OR circuit OR2 is “H”, since the output “H” is input to the first input terminal of the OR circuit OR2. That is, the pre-charge signal PRE output from the OR circuit OR2 is “H” regardless of the word pulse signal WLP. Since the pre-charge signal is input as “H” to the pre-charge circuit 12, the pre-charge operation is kept stopped.

Next, the clock signal CLK becomes “H”, as a result of which the reading operation is started, and the write signal WRI becomes “L”. Consequently, the clock signal CLK input to the second input terminal of the NOR circuit NR1 becomes “H”. Furthermore, since the test mode selecting signal TMS input to the first input terminal of the NAND circuit ND1 is “H”, and the write signal input to the second input terminal of the NAND circuit ND1 is “L”, the output of the NAND circuit ND1 is “H”.

The output “L” of the NOR circuit NR1 is input to the first input terminal of the OR circuit OR1, and the output of the write pulse generating circuit 20 is input to the second input terminal of the OR circuit OR1. As stated above, since the output of the NOR circuit NR1 is “L”, the output of the OR circuit OR1 is determined in accordance with the output of the write pulse generating circuit 20. Accordingly, the write pulse signal WRP output from the OR circuit OR1 is “L” (at a point G′), since the output of the write pulse generating circuit 20 is “L”.

The write pulse signal WRP “L” is input to the first input terminal of the OR circuit OR2, and the word line pulse signal WLP is input to the second input terminal of the OR circuit OR2. As stated above, since the output of the OR circuit OR1 is “L”, the pre-charge signal PRE output from the OR circuit OR2 is determined in accordance with the word line pulse signal WLP. Accordingly, the pre-charge signal PRE output from the OR circuit OR2 is “L”, since the word line pulse signal WLP is “L”. In such a manner, the pre-charge signal PRE is input as “L” to the pre-charge circuit 12, and thus the pre-charge operation is started.

After a predetermined time period lapses, the word line pulse signal WLP becomes “H” in order to activate the word line WL. Thereby, the pre-charge signal output from the OR circuit OR2 becomes “H”, and the pre-charge operation is stopped. Then, the reading operation is performed, and it is determined whether pre-charging of the bit lines is complete or incomplete, in order to detect whether a write recovery failure occurs or not.

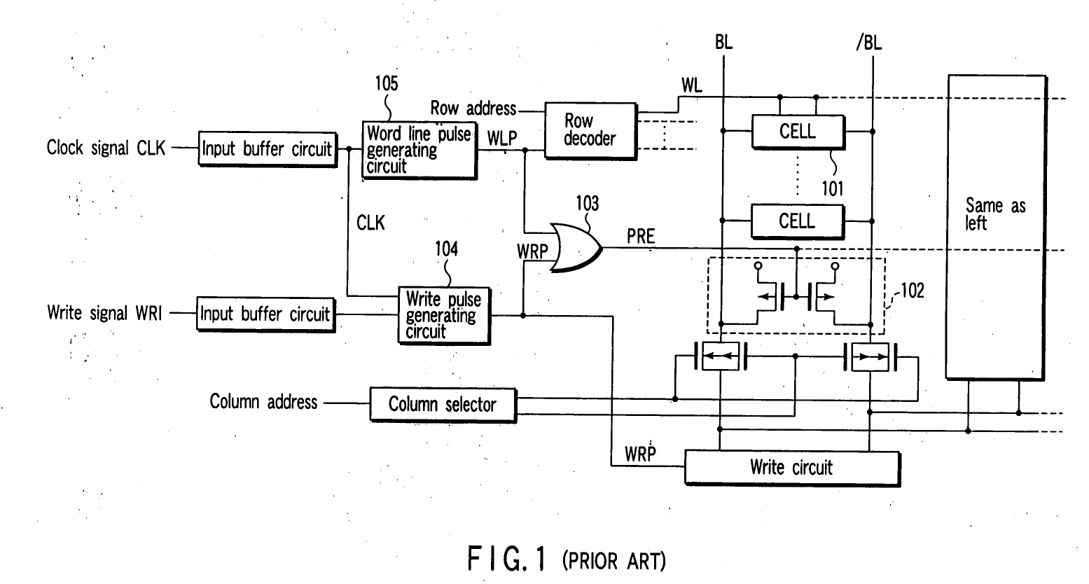

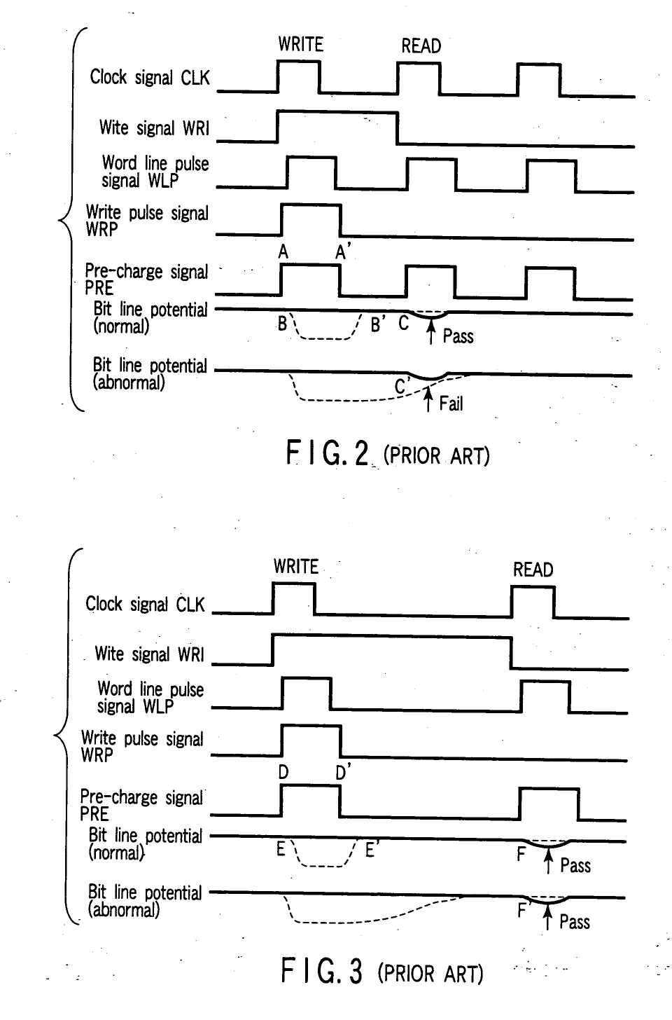

It should be noted that when the write mode selecting signal TMS is input as “L”, the operation is performed in the same regular mode as in the circuit shown in FIG. 1.

As explained above, in the embodiment of the present invention, the following test mode is provided: falling of the write pulse signal is synchronized with the rising edge of the clock signal at the start of the read time period subsequent to the write time period, and falling of the pre-charge signal is synchronized with the falling edge of the write pulse signal. Then, at the operation test time, the mode is switched from the regular mode to the above test mode. Therefore, even in the operation test at a low frequency, a write recovery failure can be detected.

The embodiment of the present invention can provide a semiconductor integrated circuit in which a write recovery failure can be detected without changing measurement means, even when a test is run at a frequency lower than that of a clock signal for synchronization.

The present invention is not limited to the above embodiment. That is, various embodiments can be achieved by changing the structure of the above embodiment or adding various structures.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A synchronous semiconductor integrated circuit which operates in synchronism with a clock signal, comprising:
a memory cell which stores information;
a bit line connected to the memory cell;
a pre-charge circuit which performs a pre-charge operation for pre-charging the bit line; and
a pre-charge controlling circuit which controls the pre-charge operation of the pre-charge circuit, and synchronizes starting of the pre-charge operation with an edge of the clock signal.

2. The semiconductor integrated circuit according to claim 1, wherein a pre-charge time period of the pre-charge controlling circuit is a time period from staring of the pre-charge operation to stopping thereof, and is set as a fixed time period which is unchanged regardless of a frequency of the clock signal.

3. The semiconductor integrated circuit according to claim 2, wherein in a case where a reading operation is performed just after a writing operation, the fixed time period is a time period from a start of a read time period in which the reading operation is performed to time when the word line connected to the memory cell has been activated.

4. The semiconductor integrated circuit according to claim 1, which further comprises:
a word line pulse generating circuit which receives the clock signal, and outputs a word line pulse signal; and
a write pulse generating circuit which receives a write signal, and outputs a write pulse signal,
wherein the pre-charge controlling circuit receives a test mode selecting signal, the write pulse signal and the word line pulse signal, and outputs a pre-charge signal to the pre-charge circuit, the test mode selecting signal is a signal for use in effecting switching between a regular mode in which a regular operation is performed and a test mode in which a test operation is performed, and the pre-charge signal is a signal which gives an instruction for starting and stopping the pre-charge operation.

5. The semiconductor integrated circuit according to claim 1, wherein a static random access memory and a logic circuit are provided to be combined, the static random access memory including the memory cells, the bit lines, the pre-charge circuit and the pre-charge controlling circuit.

6. A synchronous semiconductor integrated circuit which operates in synchronism with a clock signal, comprising:
memory cells arranged in a row direction and a column direction;
a pair of bit lines arranged in the column direction, and connected to the memory cells;
a pre-charge circuit which performs a pre-charge operation for pre-charging the pair of bit lines; and
a pre-charge controlling circuit which controls the pre-charge operation of the pre-charge circuit, the pre-charge controlling circuit causing the pre-charge operation to be stopped in synchronism with a start of a first time period of the clock signal, and to be started with a start of a second time period subsequent to the first time period of the clock signal, in a case where a writing operation is performed in the first time period of the clock signal.

7. The semiconductor integrated circuit according to claim 6, wherein a pre-charge time period of the pre-charge controlling circuit is a time period from staring of the pre-charge operation to stopping thereof, and is set as a fixed time period which is unchanged regardless of a frequency of the clock signal.

8. The semiconductor integrated circuit according to claim 7, wherein a reading operation is performed in the second time period of the clock signal, and the fixed time period is a time period from the start of the second time period to time when word line connected to the memory cells has been activated.

9. The semiconductor integrated circuit according to claim 6, wherein there is provided a test mode in which a write recovery failure is detected which occurs in a case where a reading operation is performed in the second time period of the clock signal and just after the writing operation.

10. The semiconductor integrated circuit according to claim 9, wherein the test mode selecting signal is input to the pre-charge controlling circuit, and the pre-charge controlling circuit effects switching between the test mode and a regular mode in which a regular operation is performed, in response to the test mode selecting signal.

11. The semiconductor integrated circuit according to claim 6, which further comprises:
a word line pulse generating circuit which receives the clock signal, and outputs a word pulse signal; and
a write pulse generating circuit which receives a write signal, and outputs a write pulse signal,
wherein the pre-charge controlling circuit receives a test mode selecting signal, the write pulse signal and the word line pulse signal, and outputs a pre-charge signal to the pre-charge circuit, the test mode selecting signal being provided as a signal for use in effecting switching between a regular mode in which a regular operation is performed and a test mode in which a test operation is performed, the pre-charge signal being provided as a signal which gives an instruction for starting and stopping the pre-charge operation.

12. The semiconductor integrated circuit according to claim 6, wherein a static random access memory and a logic circuit are provided to be combined, the static random access memory including the memory cells, the bit lines, the pre-charge circuit and the pre-charge controlling circuit.
